(19) United States
(12) Patent Application Publication
(10) Pub. No.: US 2025/0204104 A1
(43) Pub. Date: Jun. 19, 2025

(54) LIGHT-EMITTING DEVICE

(71) Applicant: NICHIA CORPORATION, Anan-shi (JP)

(72) Inventors: Shigeki YOSHIDA, Anan-shi (JP); Shigeyuki SUZUKI, Tokushima-shi (JP); Hiroyuki WATANABE, Itano-gun (JP)

(73) Assignee: NICHIA CORPORATION, Anan-shi (JP)

(21) Appl. No.: 18/845,146

(22) PCT Filed: Feb. 14, 2023
(86) PCT No.: PCT/JP2023/004950

§ 371 Date: Sep. 9, 2024

(30) Foreign Application Priority Data
Mar. 11, 2022 (JP) 2023-038394

(51) Int. Cl. H10H 20/851

(52) U.S. Cl. CPC H10H 20/8512; H10H 20/8514

(57) ABSTRACT

To provide a light-emitting device that emits amber-colored light and has good temperature characteristics. The light-emitting device includes a light-emitting element having a light emission peak wavelength in a range from 380 nm to 470 nm, and a wavelength conversion member including phosphors that absorb at least a part of light from the light-emitting element and emit light. The phosphors include a first phosphor having a light emission peak wavelength in a range from 535 nm to 560 nm, having a half-value width in a range from 100 nm to 120 nm, and containing a nitride containing La, Ce, and Si, and a second phosphor having a light emission peak wavelength in a range from 605 nm to less than 620 nm, having a half-value width in a range from 70 nm to 80 nm, and containing a nitride containing at least one of Ca or Sr, and Eu, Si and Al. The light-emitting device emits light within a region defined by connecting (0.545, 0.425), (0.560, 0.440), (0.609, 0.390), and (0.597, 0.390) in an xy chromaticity coordinate system of a CIE1931 chromaticity diagram.

### TECHNICAL FIELD

The present disclosure relates to a light-emitting device.

### BACKGROUND ART

An amber-colored light-emitting device is used as a turn signal being a vehicular beacon light. For example, JP 2007-213862 A proposes vehicular beacon light having a light-emitting module constituted by a semiconductor light-emitting element and a phosphor that emits amber-colored light using light from the semiconductor light emitting element as exciting light.

### SUMMARY OF INVENTION

### Technical Problem

A light-emitting device used for a vehicular beacon light is required to have improved temperature characteristics to suppress a decrease in luminous flux in a high-temperature environment. An object of an aspect of the present disclosure is to provide a light-emitting device that emits amber-colored light and has good temperature characteristics.

### Solution to Problem

A first aspect is a light-emitting device including a light-emitting element having a light emission peak wavelength in a wavelength range from 380 nm to 470 nm, and a wavelength conversion member including phosphors configured to absorb at least a part of light from the light-emitting element and emit light. The phosphors include a first phosphor having a light emission peak wavelength in a wavelength range from 535 nm to 560 nm, having a half-value width in an emission spectrum in a range from 100 nm to 120 nm, and containing a nitride having a composition containing La, Ce, and Si, and a second phosphor having a light emission peak wavelength in a wavelength range from 605 nm to less than 620 nm, having a half-value width in the emission spectrum in a range from 70 nm to 80 nm, and containing a nitride having a composition containing at least one of Ca or Sr, and Eu, Si and Al. The light-emitting device emits light having chromaticity coordinates within a region defined by a first straight line, a second straight line, a third straight line, and a fourth straight line with respect to a first point, a second point, a third point, and a fourth point in an xy chromaticity coordinate system of a CIE1931 chromaticity diagram, the first straight line connecting the first point and the second point, the second straight line connecting the second point and the third point, the third straight line connecting the third point and the fourth point, the fourth straight line connecting the fourth point and the first point, the first point having chromaticity coordinates (x, y) of (0.545, 0.425), the second point having chromaticity coordinates (x, y) of (0.560, 0.440), the third point having chromaticity coordinates (x, y) of (0.609, 0.390), the fourth point having chromaticity coordinates (x, y) of (0.597, 0.390).

### Advantageous Effects of Invention

According to an aspect of the present disclosure, a light-emitting device that emits amber-colored light and has good temperature characteristics can be provided.

### BRIEF DESCRIPTION OF DRAWINGS

FIG. 1 is a schematic cross-sectional view illustrating an example of a light-emitting device according to the present embodiment.

FIG. 2 is a schematic cross-sectional view illustrating another example of a light-emitting device according to the present embodiment.

FIG. 3 is a diagram illustrating an example of emission spectra of a first phosphor.

FIG. 4 is a diagram illustrating an example of emission spectra of a second phosphor.

FIG. 5 is a diagram illustrating an example of emission spectra of light-emitting devices according to examples and a comparative example.

FIG. 6 is a diagram illustrating a relationship between an environmental temperature and a luminous flux maintenance factor in the light-emitting devices according to the examples and the comparative example.

### DESCRIPTION OF EMBODIMENTS

In the present specification, the word “step” herein includes not only an independent step, but also a step that cannot be clearly distinguished from another step if the anticipated purpose of the step is achieved. When a plurality of substances applicable to a single component in a composition is present, the content of the single component in the composition means the total amount of the plurality of substances present in the composition, unless otherwise specified. Furthermore, with respect to an upper limit and a lower limit of numerical ranges described herein, the numerical values exemplified as the numerical range can be freely selected and combined. In the present specification, a plurality of elements separated by commas (,) in a formula representing the composition of the phosphor or light-emitting material means that at least one element among the plurality of elements is contained in the composition. In a formula representing the composition of the phosphor, any element preceding the colon (:) represents a host crystal, and any element following the colon (:) represents an activating element. Note that herein, the relationship between a color name and a chromaticity coordinate, the relationship between a wavelength range of light and a color name of monochromatic light are in accordance with JIS Z8110. A half-value width of a phosphor or a light-emitting device means a wavelength width (full width at half maximum: FWHM) in an emission spectrum at which an emission intensity is 50% of a maximum emission intensity in the emission spectrum of the phosphor or the light-emitting device. Embodiments of the present invention are described below in detail. However, the following embodiments exemplify light-emitting devices for embodying the technical concept of the present invention, and the present invention is not limited to the following light-emitting devices.

### Light-Emitting Device

A light-emitting device includes a light-emitting element having a light emission peak wavelength in a wavelength range from 380 nm to 470 nm, and a wavelength conversion member including phosphors configured to absorb at least a part of light from the light-emitting element and emit light. The phosphors include a first phosphor having a light emission peak wavelength in a wavelength range from 535 nm to 560 nm, having a half-value width in an emission spectrum in a range from 100 nm to 120 nm, and containing a nitride having a composition containing La, Ce, and Si, and a second phosphor having a light emission peak wavelength in a wavelength range from 605 nm to less than 620 nm, having a half-value width in the emission spectrum in a range from 70 nm to 80 nm, and containing a nitride having a composition containing at least one of Ca or Sr, and Eu, Si and Al. The light-emitting device emits light having chromaticity coordinates within a region defined by a first straight line, a second straight line, a third straight line, and a fourth straight line with respect to a first point, a second point, a third point, and a fourth point in an xy chromaticity coordinate system of a CIE1931 chromaticity diagram, the first straight line connecting the first point and the second point, the second straight line connecting the second point and the third point, the third straight line connecting the third point and the fourth point, the fourth straight line connecting the fourth point and the first point, the first point having chromaticity coordinates (x, y) of (0.545, 0.425), the second point having chromaticity coordinates (x, y) of (0.560, 0.440), the third point having chromaticity coordinates (x, y) of (0.609, 0.390), the fourth point having chromaticity coordinates (x, y) of (0.597, 0.390).

In a light-emitting device that emits light having specific chromaticity coordinates, a wavelength conversion member included in the light-emitting device includes a specific first phosphor and a specific second phosphor, so that a decrease in luminous flux in a high-temperature environment is effectively suppressed while the luminous flux of the light-emitting device is maintained. This is conceivable as follows, for example. Since the first phosphor and the second phosphor each have a light emission peak wavelength in a specific wavelength range, a component in a wavelength range with high luminosity factor can be increase and a component from orange to red can be increase, thereby implementing light emission of a desired amber color. Since the first phosphor and the second phosphor each have a specific composition, a light emission peak wavelength can be adjusted to a desired wavelength range while emission luminance and temperature characteristics are maintained.

The light-emitting device emits light having chromaticity coordinates within a specific region in the xy chromaticity coordinate system of the CIE1931 chromaticity diagram. The light emitted by the light-emitting device may be an amber color. The amber color of the light emitted by the light-emitting device is, for example, a color defined in Agreement Regulation No. 48 (UN_R048) 2.29.3 of the economic commission for Europe (ECE) standard being a safety standard widely used in Europe. Specifically, the color of light is a color of light in a rectangular region in which the chromaticity coordinates (x, y) of the CIE1931 chromaticity diagram are the first point (0.545,0.425), the second point (0.560,0.440), the third point (0.609,0.390), and the fourth point (0.597,0.390) as vertices.

The emission spectrum of the light-emitting device may have a light emission peak wavelength in a wavelength range from 590 nm to 620 nm, and a half-value width of 90 nm or less. The light emission peak wavelength in the emission spectrum of the light-emitting device may be preferably 595 nm or more or 600 nm or more, and may be preferably 610 nm or less or 605 nm or less. The half-value width in the emission spectrum of the light-emitting device may be preferably 85 nm or less or 80 nm or less, and may be preferably 70 nm or more or 75 nm or more. The emission spectrum of the light-emitting device is measured at a room temperature (for example, 25° C.) unless otherwise specified.

In the emission spectrum of the light-emitting device, when an integrated value of an emission intensity in a wavelength range from 600 nm to 800 nm is set as Z¹ and an integrated value of an emission intensity in a wavelength range from 400 nm to less than 600 nm is set as Z², an emission intensity ratio Z²/Z¹ may be, for example, 0.600 or more, preferably 0.620 or more, 0.630 or more, 0.652 or more, or 0.660 or more. The emission intensity ratio Z²/Z¹ may be, for example, 0.750 or less or 0.730 or less.

Since the light-emitting device includes the wavelength conversion member including the specific first phosphor and the specific second phosphor, a decrease in luminous flux in a high-temperature environment is effectively suppressed. Specifically, a luminous flux maintenance factor, which is the ratio of the luminous flux at an ambient temperature of 135° C. to the luminous flux at an ambient temperature of 25° C., may be greater than 70%, for example. The luminous flux maintenance factor may be preferably 71% or more, 72% or more, 73% or more, or 74% or more. The luminous flux maintenance factor may be, for example, 90% or less, 85% or less, or 80% or less. The luminous flux maintenance factor is calculated by measuring the luminous flux when a drive current of the light-emitting device is 150 mA, for example.

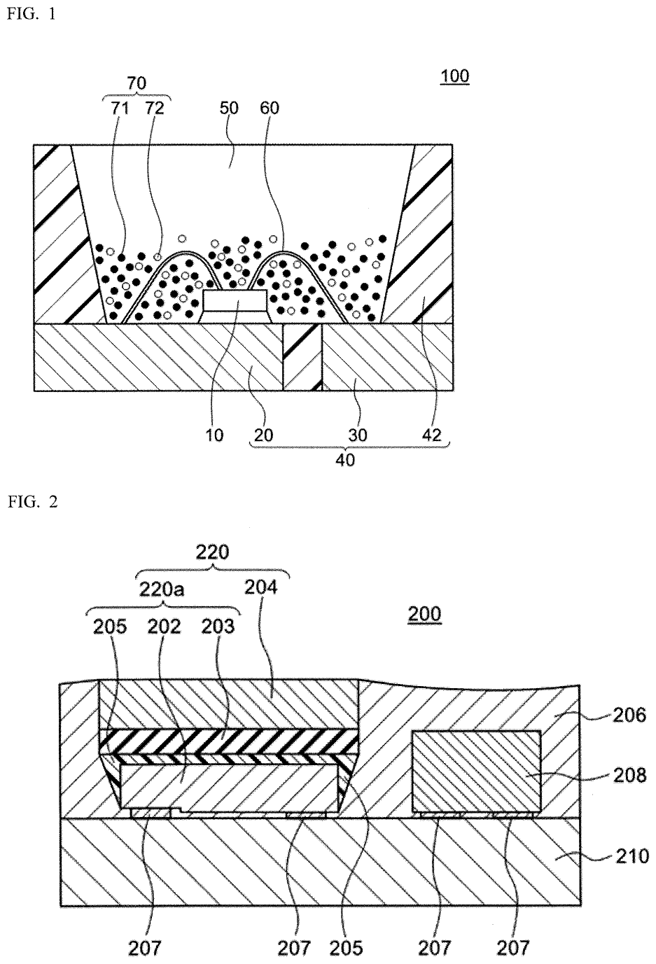

An example of the configuration of the light-emitting device is described below with reference to the drawings. FIG. 1 is an example of a schematic cross-sectional view of the light-emitting device. A light-emitting device 100 includes a light-emitting element 10 and a wavelength conversion member 50. A phosphor 70 included in the wavelength conversion member 50 includes, for example, at least two types of phosphors: a first phosphor 71 having a light emission peak wavelength in a range from 535 nm to 560 nm and a second phosphor 72 having a light emission peak wavelength in a range from 605 nm to less than 620 nm.

The light-emitting device 100 includes the light-emitting element 10 made of a gallium nitride compound semiconductor having a light emission peak wavelength in a range from 380 nm to 470 nm, and a molded body 40 on which the light-emitting element 10 is mounted. The molded body 40 is formed by integrally molding a first lead 20, a second lead 30, and a resin portion 42. Instead of the resin portion 42, the molded body 40 can also be formed by a known method using ceramics as a material. The molded body 40 forms a recessed portion including a bottom surface and a lateral surface, and the light-emitting element 10 is mounted on the bottom surface of the recessed portion. The light-emitting element 10 includes a pair of positive and negative electrodes, and the pair of the positive and negative electrodes are electrically connected to the first lead 20 and the second lead 30, respectively, via wires 60. The light-emitting element 10 is covered with the wavelength conversion member 50. The wavelength conversion member 50 includes, for example, the phosphor 70 for converting a wavelength of light from the light-emitting element 10 and a resin, and the phosphor 70 includes at least two types of phosphors: the first phosphor 71 and the second phosphor 72.

FIG. 2 is a schematic cross-sectional view illustrating another example of the configuration of the light-emitting device. A light-emitting device 200 includes a light-emitting layered portion 220 having a light-emitting surface of the light-emitting device 200 and a covering member 206. The light-emitting layered portion 220 is provided on a substrate 210 and includes a light-emitting unit 220a including a light-emitting element 202 and a wavelength conversion member 203. The light-emitting laminated portion 220 is covered with the covering member 206 except for an upper surface of a light-transmissive member 204, which is a light emission surface. The covering member 206 reflects both light emitted by the light-emitting element 202 and light emitted by phosphors included in the wavelength conversion member 203. The light-emitting element 202 is provided on the substrate 210 via a conductive member 207, and emits light having a light emission peak wavelength in a range from 380 nm to 470 nm when a voltage is applied thereto via a wiring formed on the substrate 210. The wavelength conversion member 203 is provided on a light-emitting surface of the light-emitting element 202, and converts the wavelength of the light emitted from the light-emitting element 202 by the phosphors included in the wavelength conversion member 203. The phosphors included in the wavelength conversion member 203 include at least two types of phosphors that are the first phosphor and the second phosphor described above. The wavelength conversion member 203 is bonded to the light-emitting element via an adhesive layer 205.

The light-emitting device 200 may include a semiconductor element 208 such as a protective element for preventing the light-emitting element 202 from being damaged by the application of excessive voltage. The semiconductor element 208 may be disposed on the substrate 210 via the conductive member 207 and covered with the covering member 206. Note that the semiconductor element 208 described herein includes no light-emitting element. The semiconductor element 208 is a Zener diode, for example.

### Light-Emitting Element

The light emission peak wavelength of the light-emitting element is in a range from 380 nm to 470 nm, and is preferably in a range from 420 nm to 460 nm from the viewpoint of emission efficiency. A light-emitting device that emits mixed light of light from the light-emitting element and fluorescent light from the phosphors can be configured by using, as an excitation light source, a light-emitting element having a light emission peak wavelength in this range. Further, the light emitting from the light-emitting element to the outside can be effectively utilized, and thus the loss of light emitting from the light-emitting device can be reduced and a highly efficient light-emitting device can be achieved. Since the light emission peak wavelength is on a wavelength side longer than a near-ultraviolet region and an amount of an ultraviolet component is small, safety as a light source and luminous efficiency are excellent.

The half-value width of the emission spectrum of the light-emitting element may be, for example, 30 nm or less. A semiconductor light-emitting element, such as a light-emitting diode (LED), is preferably used as the light-emitting element. By using a semiconductor light-emitting element as a light source, it is possible to achieve a stable light-emitting device that exhibits high efficiency and high output linearity with respect to an input and that is strong against mechanical impact. An example of the semiconductor light-emitting element that can be used includes a semiconductor light-emitting element using a nitride-based semiconductor and emitting blue light, green light, or the like.

### Wavelength Conversion Member

The wavelength conversion member can contain, for example, a phosphor and a resin, but may contain only a phosphor, or may be composed of a phosphor and an inorganic material. The wavelength conversion member may include, as the phosphor, at least one first phosphor that absorbs light emitted from the light-emitting element and emits yellow light and at least one second phosphor that absorbs the light emitted from the light-emitting element and emits red light. The first phosphor and the second phosphor have compositions different from each other. By appropriately selecting the composition ratio of the first phosphor and the second phosphor, characteristics such as the emission efficiency of the light-emitting device and the chromaticity coordinates of emitted light can be set in a desired range.

Examples of the resin constituting the wavelength conversion member include a silicone resin, an epoxy resin, a modified silicone resin, a modified epoxy resin, and an acrylic resin. For example, the refractive index of a silicone resin may be in a range from 1.35 to 1.55, more preferably in a range from 1.38 to 1.43. When the refractive index of the silicone resin is within these ranges, the silicone resin has excellent transmissivity, and can be suitably used because the silicone resin can efficiently extract light to the outside of the light-emitting device. The refractive index of the silicone resin is the refractive index after curing, and is measured in accordance with JIS K 7142:2008. The wavelength conversion member may further include a light-diffusing material in addition to the resin and the phosphor. When the wavelength conversion member includes a light-diffusing material, directivity from the light-emitting element can be alleviated, and a viewing angle can be increased. Examples of the light-diffusing material include inorganic materials such as silicon oxide, titanium oxide, zinc oxide, zirconium oxide, and aluminum oxide.

### First Phosphor

The first phosphor may have a light emission peak wavelength in a range from 535 nm to 560 nm. The light emission peak wavelength of the first phosphor may be preferably 540 nm or more, 543 nm or more, or 545 nm or more, and preferably 555 nm or less or 550 nm or less. The half-value width of the emission peak of the first phosphor may be, for example, in a range from 100 nm to 120 nm, preferably 105 nm or more or 110 nm or more, and preferably 115 nm or less. The first phosphor may be, for example, a yellow phosphor that emits light in a yellow region.

The first phosphor contains a nitride having a composition containing at least lanthanum (La), cerium (Ce), and silicon (Si), and may contain a nitride further containing at least one element M¹ selected from rare earth elements other than La and Ce in the composition. Examples of the rare earth elements represented by M¹, other than La and Ce, include scandium (Sc), yttrium (Y), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu). The element M¹ may include at least one selected from the group consisting of Y, Gd, and Lu, and may include at least Y.

For example, when the number of moles of Si is 6, the composition of the nitride contained in the first phosphor may be such that the total number of moles of La, Ce, and M¹ is in a range from 2.7 to 3.3, the number of moles of M¹ is in a range from 0 to 1.2, the number of moles of nitrogen atoms (N) is in a range from 10 to 12, and the number of moles of Ce is greater than 0 and 1.2 or less. In the composition of the nitride contained in the first phosphor, when the number of moles of Si is 6, preferably, the total number of moles of La, Ce, and M¹ may be 2.8 or more or 2.9 or more, and may be 3.2 or less or 3.1 or less. In the composition of the nitride contained in the first phosphor, when the number of moles of Si is 6, preferably, the number of moles of M¹ may be 0.1 or more or 0.3 or more, and may be 1.0 or less, or 0.8 or less. In the composition of the nitride contained in the first phosphor, when the number of moles of Si is 6, preferably, the number of moles of N may be 10.3 or more or 10.5 or more, and may be 11.5 or less or 11.3 or less. In the composition of the nitride contained in the first phosphor, when the number of moles of Si is 6, preferably, the number of moles of Ce may be 0.15 or more or 0.3 or more, and 1.0 or less or 0.9 or less.

The nitride contained in the first phosphor may have a theoretical composition represented by Formula (1a) below, for example.

La₍₃₋ₘ₎M¹ₘSi₆N₁₁:Ce (0≤m≤1.2) (1a)

In Formula (1a) above, M¹ represents at least one element selected from the rare earth elements other than La and Ce. The total molar content of Y, Gd, and Lu in M¹ may be, for example, 90 mol % or more, 95 mol % or more, or 99 mol % or more. Preferably, m may be 0.1 or more or 0.3 or more, and may be 1.0 or less or 0.8 or less.

When M¹ is Y in Formula (1a) above, the nitride contained in the first phosphor may have a theoretical composition substantially represented by Formula (1b) below, for example.

La₍₃₋ₘ₎YₘSi₆N₁₁:Ce (0<m≤1.2) (1b)

Preferably, m may be 0.1 or more or 0.3 or more, and may be 1.0 or less or 0.8 or less.

The content of the first phosphor in the wavelength conversion member may be, for example, in a range from 20 mass % to 65 mass % relative to the total mass of the phosphors included in the wavelength conversion member. The content of the first phosphor may be preferably 25 mass % or more or 30 mass % or more, and preferably 60 mass % or less or 55 mass % or less. The wavelength conversion member may include one type of first phosphor alone, or may include two or more types in combination.

### Second Phosphor

The second phosphor may have a light emission peak wavelength in a range from 605 nm to less than 620 nm. The light emission peak wavelength of the second phosphor may be preferably 607 nm or more, 608 nm or more, or 610 nm or more, and preferably 618 nm or less, 617 nm or less, or 615 nm or less. The half-value width of the emission peak of the second phosphor may be, for example, in a range from 70 nm to 80 nm, preferably may be 72 nm or more, and preferably 77 nm or less or 75 nm or less. The second phosphor may be, for example, a red phosphor that emits light in a red region.

The difference in the light emission peak wavelength between the second phosphor and the first phosphor may be, for example, 85 nm or less, preferably 75 nm or less or 70 nm or less. The difference in the light emission peak wavelength between the second phosphor and the first phosphor may be, for example, 45 nm or more or 55 nm or more. When the difference in the light emission peak wavelength between the second phosphor and the first phosphor is within the above range, the half-value width in the emission spectrum of the light-emitting device can be further narrowed, so that a desired amber color can be achieved.

The second phosphor may include a nitride having a composition containing at least one of calcium (Ca) or strontium (Sr), europium (Eu), silicon (Si), aluminum (Al), and nitrogen (N), and may include a nitride further including at least one element M² selected from Group 2 elements other than Ca and Sr in the composition. The element M² may include at least one selected from the group consisting of Ba and Mg.

For example, when the number of moles of Al is 1, the composition of the nitride contained in the second phosphor may be such that the number of moles of Ca is greater than 0 and less than 1, the number of moles of Sr is in a range from 0 to less than 1, the number of moles of Eu is in a range from 0.002 to 0.08, the total number of moles of Ca, Sr and Eu is in a range from 0.8 to 1.1, the number of moles of Si is in a range from 0.8 to 1.2, and the number of moles of nitrogen atoms (N) is in a range from 2.5 to 3.2. In the composition of the nitride contained in the second phosphor, when the number of moles of Al is 1, preferably, the number of moles of Ca may be 0.01 or more or 0.02 or more, and 0.4 or less or 0.2 or less. In the composition of the nitride contained in the second phosphor, when the number of moles of Al is 1, preferably, the number of moles of Sr may be 0.6 or more or 0.8 or more, and may be 0.99 or less or 0.98 or less. In the composition of the nitride contained in the second phosphor, when the number of moles of Al is 1, preferably, the number of moles of Eu may be 0.0025 or more or 0.003 or more, and may be 0.07 or less or 0.06 or less. In the composition of the nitride contained in the second phosphor, when the number of moles of Al is 1, preferably, the total number of moles of Ca, Sr, and Eu may be 0.85 or more or 0.90 or more, and may be 1.08 or less or 1.06 or less. In the composition of the nitride contained in the second phosphor, when the number of moles of Al is 1, preferably, the number of moles of Si may be 0.85 or more or 0.9 or more, and may be 1.18 or less or 1.15 or less. In the composition of the nitride contained in the second phosphor, when the number of moles of Al is 1, preferably, the number of moles of N may be 2.55 or more or 2.6 or more, and may be 3.15 or less or 3.1 or less.

The nitride contained in the second phosphor may have a theoretical composition represented by Formula (2a) below, for example.

SrₙM²₍₁₋ₙ₎AlSiN₃:Eu (0≤n≤1) (2a)

In Formula (2a) above, M² represents at least one element selected from the group consisting of Ca, Ba, and Mg. The molar content of Ca in M² may be, for example, 80 mol % or more or 90 mol % or more. Preferably, n may be 0.6 or more or 0.8 or more, and may be 0.99 or less or 0.98 or less.

When M² is Ca in formula (1a) above, the nitride contained in the second phosphor may have, for example, a theoretical composition substantially represented by formula (2b) below.

SrₙCa₍₁₋ₙ₎AlSiN₃:Eu (0≤n≤1) (2b)

Preferably, n may be 0.6 or more or 0.8 or more, and may be 0.99 or less or 0.98 or less.

The content of the second phosphor in the wavelength conversion member may be, for example, in a range from 35 mass % to 80 mass % relative to the total mass of the phosphors included in the wavelength conversion member. The content of the second phosphor may be preferably 40 mass % or more or 45 mass % or more, and preferably 75 mass % or less or 70 mass % or less. The wavelength conversion member may include one type of second phosphor alone, or may include two or more types in combination.

In the wavelength conversion member, the ratio of the content of the second phosphor to the total content of the first phosphor and the second phosphor may be, for example, in a range from 35 mass % to 80 mass %. In the wavelength conversion member, the ratio of the content of the second phosphor to the total content of the first phosphor and the second phosphor may be preferably 40 mass % or more, 45 mass % or more, or 50 mass % or more, and preferably 75 mass % or less or 70 mass % or less.

The wavelength conversion member may further include another phosphor in addition to the first phosphor and the second phosphor. The other phosphor may have a light emission peak wavelength in a wavelength range from 450 nm to 680 nm, for example. The another phosphor may contain at least one selected from the group consisting of phosphors having a composition such as (Y, Gd, Lu)₃(Al, Ga)₅O₁₀, (Ca, Sr, Ba)₂Si₅N₈, (Ca, Sr, Ba)Si₂O₂N₂, (Ca, Sr, Ba)₂SiO₄, α-SiAlON, and β-SiAlON. An activator included in these phosphors may be preferably Ce or Eu, more preferably Ce.

Another aspect of the present invention also includes use of the first phosphor and the second phosphor in manufacturing the above-described light-emitting device, use of the first phosphor and the second phosphor in the above-described light-emitting device, and the first phosphor and the second phosphor used in the above-described light-emitting device.

### EXAMPLES

The present invention is described below in detail through examples; however, the present invention is not limited to these examples.

### Reference Examples

As yellow phosphors, phosphor 1 having a theoretical composition represented by Y₃Al₅O₁₂:Ce (hereinafter, sometimes abbreviated as YAG), phosphor 2 having a theoretical composition represented by La₃Si₆N₁₁:Ce (hereinafter, sometimes abbreviated as LSN), and phosphors 3 to 6 having different light emission peak wavelengths and a theoretical composition represented by La₍₃₋ₘ₎YₘSi₆N₁₁:Ce (0<m≤ 0.75; hereinafter, sometimes abbreviated as LYSN) were prepared. As red phosphors, phosphor 7 having a theoretical composition represented by BaₖSr₍₂₋ₖ₎Si₅N₈:Eu (0.80≤k<1.50; hereinafter, sometimes referred to as BSESN) and phosphors 8 to 11 having different light emission peak wavelengths and a theoretical composition represented by SrₙCa₍₁₋ₙ₎AlSiN₃:Eu (0≤n<1; hereinafter, sometimes referred to as SCASN) were prepared.

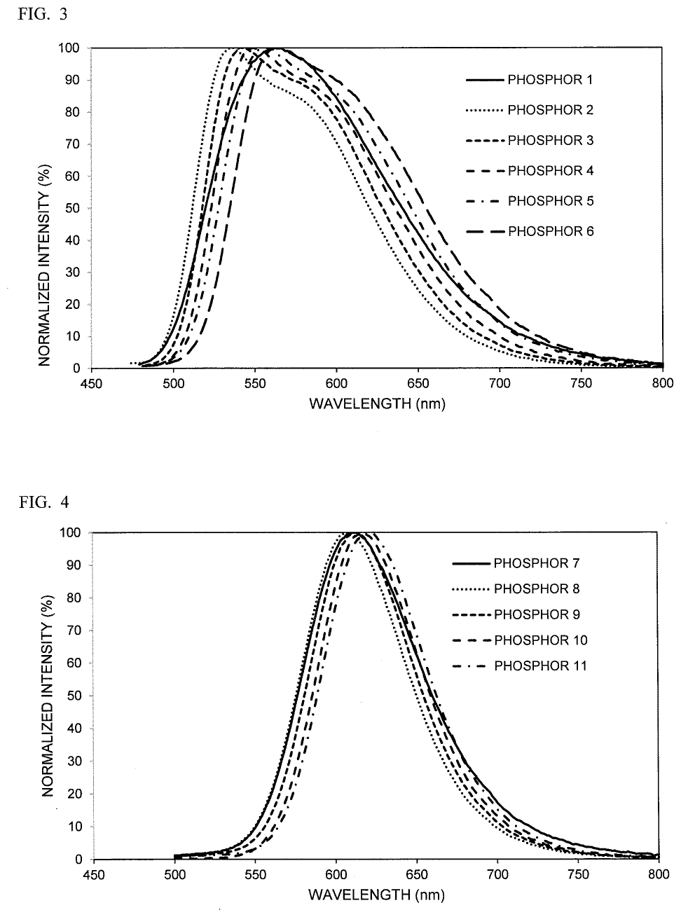

For the prepared phosphors, the xy chromaticity coordinates, relative luminance (Y), relative emission energy (ENG), light emission peak wavelength (λp), and half-value width of the CIE1931 chromaticity diagram were measured at 25° C. by using a quantum efficiency measurement system (QE-2000 manufactured by Otsuka Electronics Co., Ltd.). The results are indicated in Table 1 below. Note that the relative luminance (Y) and the relative emission energy (ENG) were expressed as relative values with the phosphor 1 (YAG) as 100%. The ENG retention rate (%) was calculated by dividing the ENG at 150° C. by the ENG at 25° C. The results are indicated in Table 1 below. FIGS. 3 and 4 illustrate the emission spectra of the phosphors normalized by the maximum emission energy of each phosphor.

TABLE 1

| | | Light emission characteristics | | | | | | ENG |
|---|---|---|---|---|---|---|---|---|
| | | | | | | | Half-value | retention |
| | Composition | x | y | Y(%) | ENG(%) | λp(nm) | width | rate (%) |
| Phosphor 1 | YAG | 0.465 | 0.521 | 100.0 | 100.0 | 561 | 121 | 96.7 |
| Phosphor 2 | LSN | 0.428 | 0.552 | 100.9 | 89.9 | 536 | 109 | 96.0 |
| Phosphor 3 | LYSN | 0.449 | 0.538 | 99.8 | 90.9 | 544 | 111 | 97.4 |
| Phosphor 4 | | 0.467 | 0.523 | 92.3 | 87.7 | 550 | 113 | 97.4 |
| Phosphor 5 | | 0.482 | 0.511 | 86.8 | 86.9 | 554 | 118 | 99.7 |
| Phosphor 6 | | 0.504 | 0.492 | 76.7 | 82.4 | 563 | 121 | 89.4 |
| Phosphor 7 | BSESN | 0.613 | 0.387 | 52.6 | 82.4 | 612 | 84 | 96.2 |
| Phosphor 8 | SCASN | 0.608 | 0.391 | 63.7 | 88.8 | 608 | 75 | 97.7 |
| Phosphor 9 | | 0.623 | 0.377 | 60.1 | 92.8 | 613 | 74 | 97.1 |
| Phosphor 10 | | 0.633 | 0.367 | 53.9 | 91.2 | 617 | 73 | 97.0 |
| Phosphor 11 | | 0.642 | 0.357 | 48.3 | 88.6 | 620 | 73 | 95.9 |

From Table 1 above, it can be seen that the phosphors 2 to 5 have light emission peak wavelengths in a wavelength range from 535 nm to 560 nm and half-value widths in a range from 100 nm to 120 nm in the emission spectra, and contain a nitride having the above composition (la), and thus correspond to the first phosphor described above. It can also be seen that the phosphors 8 to 10 have light emission peak wavelengths in a wavelength range from 605 nm to less than 620 nm and half-value widths in a range from 70 nm to 80 nm in the emission spectra, and contain a nitride having the above composition (2a), and thus correspond to the second phosphor described above.

### First Example

An LED chip made of a nitride semiconductor having a light emission peak wavelength of 455 nm was prepared as a light-emitting element. As illustrated in FIG. 1, the light-emitting element 10 was disposed on the bottom surface of the recessed molded body 40, and was connected to the first lead 20 and the second lead 30 by the wires 60, respectively. The phosphor 2 as a yellow phosphor and the phosphor 9 as a red phosphor were combined at a mixing ratio shown in Table 2 below and added to and mixed with a silicone resin to disperse the phosphors in the silicone resin so that the chromaticity coordinates (x, y) of mixed color light emitted by the light-emitting device are (0.563, 0.416), thereby obtaining a composition for a wavelength conversion member. The composition for a wavelength conversion member was injected into the recessed portion of the molded body 40, and the silicone resin was cured to form the wavelength conversion member 50, thereby obtaining the light-emitting device 100.

Second to Eleventh Examples and First to Fifth Comparative Examples Light-emitting devices were obtained in the same manner as in the first example except that the types and mixing ratios of phosphors used were changed as shown in Table 2 below. The mixing ratio (%) shown in Table 2 below is a ratio (%) of the mass of each phosphor when the total mass of the yellow phosphor and the red phosphor is set to 100%.

TABLE 2

| | | | Mixing ratio (%) | |
|---|---|---|---|---|
| | Yellow | Red | Yellow | Red |
| | phosphor | phosphor | phosphor | phosphor |
| First example | Phosphor 2 | Phosphor 9 | 52.2 | 47.8 |
| Second example | Phosphor 2 | Phosphor 10 | 62.0 | 38.0 |
| Third example | Phosphor 3 | Phosphor 8 | 31.0 | 69.0 |
| Fourth example | Phosphor 3 | Phosphor 9 | 50.0 | 50.0 |
| Fifth example | Phosphor 3 | Phosphor 10 | 60.2 | 39.8 |
| Sixth example | Phosphor 4 | Phosphor 8 | 35.0 | 65.0 |
| Seventh example | Phosphor 4 | Phosphor 9 | 52.5 | 47.5 |
| Eighth example | Phosphor 4 | Phosphor 10 | 64.1 | 35.9 |
| Ninth example | Phosphor 5 | Phosphor 8 | 29.6 | 70.5 |
| Tenth example | Phosphor 5 | Phosphor 9 | 47.8 | 52.3 |
| Eleventh example | Phosphor 5 | Phosphor 10 | 56.3 | 43.7 |
| First comparative | Phosphor 1 | Phosphor 7 | 43.8 | 56.3 |
| example | | | | |
| Second comparative | Phosphor 1 | Phosphor 9 | 49.6 | 50.4 |
| example | | | | |
| Third comparative | Phosphor 5 | Phosphor 11 | 70.9 | 29.1 |
| example | | | | |
| Fourth comparative | Phosphor 6 | Phosphor 9 | 57.1 | 42.9 |
| example | | | | |
| Fifth comparative | Phosphor 6 | Phosphor 10 | 65.3 | 34.7 |
| example | | | | |

### Evaluation of Light-Emitting Device

### Emission Spectrum

For the light-emitting devices obtained in the first to eleventh examples and the first to fourth comparative examples, emission spectra indicating emission intensity (ENG) with respect to wavelength (nm) were measured at a room temperature of 25° C. by using a spectrofluorophotometer. On the basis of the obtained emission spectra, the light emission peak wavelength, the half-value width, and the emission intensity ratio Z²/Z¹ as the ratio of the integrated value Z² of the emission intensity in a wavelength range from 400 nm to less than 600 nm to the integrated value Z¹ of the emission intensity in a wavelength range from 600 nm to 800 nm were calculated. The results are shown in Table 3.

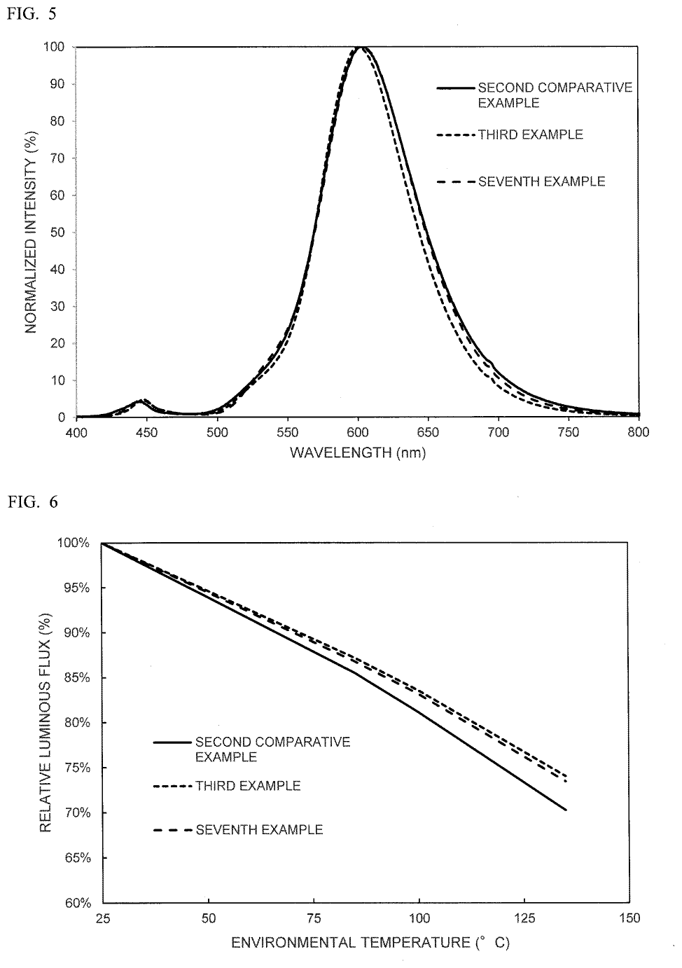

FIG. 5 illustrates emission spectra of the light-emitting devices obtained in the third example, the seventh example, and the second comparative example normalized by the maximum emission intensity in each emission spectrum.

### Relative Luminous Flux (Po)

The light-emitting devices obtained in the first to eleventh examples and the first to fourth comparative examples were caused to emit light at a drive current of 150 mA in a room temperature (25° C.) environment. The total luminous flux of each light-emitting device was measured by a total luminous flux measuring device using an integrating sphere, and the relative luminous flux (Po; %) of each light-emitting device was calculated when the total luminous flux of the light-emitting device of the second comparative example was taken as 100%.

### Luminous Flux Maintenance Factor

The light-emitting devices obtained in the first to eleventh examples and the first to fourth comparative examples were placed in a thermostatic chamber, the temperature was controlled so that the ambient (atmosphere) temperature Ta and Tj (junction temperature) of light-emitting elements are substantially the same (Ta=Tj), the light-emitting devices were pulse-driven at a drive current of 150 mA, and the total luminous flux of the light-emitting devices were measured in an environment of 135° C. in the same manner as described above. For each light-emitting device, the ratio of the total luminous flux at 135° C. to the total luminous flux at 25° C. was calculated as the luminous flux maintenance factor (%). The relative luminous flux (%) of each light-emitting device at 135° C. was calculated with the total luminous flux of the light-emitting device of the second comparative example at 135° C. as 100%. The results are shown in Table 3.

TABLE 3

| | 25° C. | | | | | |
|---|---|---|---|---|---|---|
| | | Light | | | | |
| | | emission | | Emission | 135° C. | |
| | Relative | peak | | intensity | Luminous flux | Relative |
| | luminous | wavelength | Half-value | ratio | maintenance | luminous |
| | flux (%) | (nm) | width (nm) | Z²/Z¹ | factor (%) | flux (%) |
| First example | 97.2 | 603 | 76 | 0.688 | 74 | 102.3 |
| Second example | 95.9 | 606 | 77 | 0.653 | 74 | 101.7 |
| Third example | 101.1 | 602 | 75 | 0.725 | 74 | 106.5 |
| Fourth example | 100.7 | 603 | 77 | 0.678 | 74 | 106.4 |
| Fifth example | 98.9 | 606 | 78 | 0.643 | 74 | 104.8 |
| Sixth example | 99.4 | 602 | 77 | 0.707 | 73 | 103.4 |
| Seventh example | 100.5 | 603 | 79 | 0.662 | 73 | 105.1 |
| Eighth example | 98.5 | 606 | 80 | 0.630 | 74 | 103.1 |
| Ninth example | 98.4 | 602 | 80 | 0.687 | 74 | 103.1 |
| Tenth example | 97.7 | 605 | 82 | 0.639 | 73 | 102.2 |
| Eleventh example | 95.7 | 607 | 83 | 0.607 | 74 | 100.3 |
| First comparative | 94.7 | 602 | 90 | 0.607 | 66 | 88.9 |
| example | | | | | | |
| Second comparative | 100.0 | 602 | 81 | 0.651 | 70 | 100.0 |
| example | | | | | | |
| Third comparative | 91.2 | 610 | 87 | 0.570 | 73 | 95.2 |
| example | | | | | | |
| Fourth comparative | 95.5 | 604 | 83 | 0.620 | 73 | 99.1 |
| example | | | | | | |
| Fifth comparative | 94.2 | 606 | 90 | 0.594 | 74 | 99.0 |
| example | | | | | | |

### Luminous Flux Maintenance Factor

For each of the light-emitting devices obtained in the third example, the seventh example, and the second comparative example, the ratio of the total luminous flux in each environment of 85° C., 100° C., and 135° C. to the total luminous flux when the light-emitting device was caused to emit light at a drive current of 150 mA in a room temperature (25° C.) environment was calculated as a luminous flux maintenance factor (%). FIG. 6 illustrates changes in relative luminous flux (%) with respect to ambient temperature for the light-emitting devices according to the third example, the seventh example, and the second comparative example.

As shown in Table 3 above, the light-emitting devices of the third, fourth, and seventh examples have higher luminous flux at a room temperature of 25° C. than the light-emitting device of the second comparative example serving as a reference. The light-emitting devices of the first to eleventh examples in which LYSN and SCASN are combined have higher luminous flux maintenance factors than that of the light-emitting device of the second comparative example. It can be seen that the relative luminous flux in a high temperature state is higher in the light-emitting devices of all the examples than in the light-emitting device of the second comparative example.

In an example in which LYSN and SCASN are combined, an optimum light emission peak wavelength exists for each of LYSN and SCASN. It can be seen that the optimum light emission peak wavelength in LYSN is preferably in a range from 535 nm to 555 nm because the relative luminous flux is higher in the examples using the phosphors 3, 4 and 5 than in the comparative example using the phosphor 6, and is more preferably in a range from 545 nm to 550 nm because the relative luminous flux is higher in the examples using the phosphors 3 and 4 than in the other examples.

The relative luminous flux is higher in the examples and the comparative examples using the phosphors 8 and 9 than in the examples and the comparative examples using the phosphors 10 and 11. Therefore, the optimum light emission peak wavelength in SCASN is preferably in a range from 608 nm to 615 nm, and is more preferably in a range from 608 nm to 610 nm because the relative luminous flux is higher in the example using the phosphor 8 than in the example using the phosphor 9.

As shown in Table 3 above, by combining LYSN and SCASN, the half-value width of the emission spectrum can be narrowed. As can be seen from the emission spectra of the respective phosphors illustrated in FIG. 4, the emission intensity of LYSN is lower than the emission intensity of BSESN on a long wavelength side, which is disadvantageous for improving the luminous flux of the light-emitting device. Therefore, it is considered that the combination of LYSN and SCASN is advantageous in improving the luminous flux of the light-emitting device also in terms of the shape of the spectrum in the light-emitting device that emits amber light. The phosphors to be combined not only have high luminance as phosphors but also have a narrow half-value width in the emission spectrum and a small difference in the light emission peak wavelength between the first phosphor and the second phosphor, whereby a spectrum having a narrow half-value width in the light-emitting device that emits amber light can be formed.

The light-emitting device of the present disclosure can be used for, for example, a marker lamp for a vehicle, a display device, a lighting fixture, a display, a backlight light source of a liquid crystal display, and the like.

The disclosure of Japanese Patent Application No. 2022-038394 (filing date: Mar. 11, 2022) is incorporated herein by reference in its entirety. All publications, patent applications, and technical standards described in the present specification are incorporated herein by reference to the same extent as a case in which the incorporation by reference of each individual publication, patent application, and technical standard is specifically and individually indicated to be incorporated by reference.

1. A light-emitting device comprising:
a light-emitting element having a light emission peak wavelength in a wavelength range from 380 nm to 470 nm; and
a wavelength conversion member comprising phosphors configured to absorb at least a part of light from the light-emitting element and emit light, wherein
the phosphors comprise a first phosphor having a light emission peak wavelength in a wavelength range from 535 nm to 560 nm, having a half-value width in an emission spectrum in a range from 100 nm to 120 nm, and containing a nitride having a composition containing La, Ce, and Si, and a second phosphor having a light emission peak wavelength in a wavelength range from 605 nm to less than 620 nm, having a half-value width in the emission spectrum in a range from 70 nm to 80 nm, and containing a nitride having a composition containing at least one of Ca or Sr, and Eu, Si and Al, and
the light-emitting device emits light having chromaticity coordinates within a region defined by a first straight line, a second straight line, a third straight line, and a fourth straight line with respect to a first point, a second point, a third point, and a fourth point in an xy chromaticity coordinate system of a CIE1931 chromaticity diagram, the first straight line connecting the first point and the second point, the second straight line connecting the second point and the third point, the third straight line connecting the third point and the fourth point, the fourth straight line connecting the fourth point and the first point, the first point having chromaticity coordinates (x, y) of (0.545, 0.425), the second point having chromaticity coordinates (x, y) of (0.560, 0.440), the third point having chromaticity coordinates (x, y) of (0.609, 0.390), the fourth point having chromaticity coordinates (x, y) of (0.597, 0.390).

2. The light-emitting device according to claim 1, wherein
when at least one element selected from rare earth elements other than La and Ce is M¹ and the number of moles of Si is 6, the first phosphor has a composition in which the total number of moles of La, Ce, and M¹ is in a range from 2.7 to 3.3, the number of moles of M¹ is in a range from 0 to 1.2, the number of moles of nitrogen atoms is in a range from 10 to 12, and the number of moles of Ce is greater than 0 and 1.2 or less.

3. The light-emitting device according to claim 1, wherein
the first phosphor has a theoretical composition represented by Formula (1a) below,
La₍₃₋ₘ₎M¹ₘSi₆N₁₁:Ce (0≤m≤1.2) (1a)
(in Formula (1) above, M¹ represents at least one element selected from rare earth elements other than La and Ce, and the total molar content of Y, Gd, and Lu in M¹ is 90 mol % or more).

4. The light-emitting device according to any one of claims 1 to 3, wherein
when the number of moles of Al is 1, the second phosphor has a composition in which the number of moles of Ca is greater than 0 and less than 1, the number of moles of Sr is in a range from 0 to less than 1, the number of moles of Eu is in a range from 0.002 to 0.05, the total number of moles of Ca, Sr and Eu is in a range from 0.8 to 1.1, the number of moles of Si is in a range from 0.8 to 1.2, and the number of moles of nitrogen atoms is in a range from 2.5 to 3.2.

5. The light-emitting device according to any one of claims 1 to 3, wherein
the second phosphor has a theoretical composition represented by Formula (2a) below,
SrₙM²₍₁₋ₙ₎AlSiN₃:Eu (0≤n≤1) (2a)
(In Formula (2a) above, M² represents at least one element selected from the group consisting of Ca, Ba, and Mg).

6. The light-emitting device according to any one of claims 1 to 5, wherein
when a drive current of the light-emitting device is 150 mA, a luminous flux maintenance factor being a ratio of a luminous flux at an ambient temperature of 135° C. to a luminous flux at an ambient temperature of 25° C. is greater than 70%.

7. The light-emitting device according to any one of claims 1 to 6, wherein
in an emission spectrum of the light-emitting device, a ratio Z²/Z¹ of an integrated value Z² of an emission intensity in a wavelength range from 400 nm to less than 600 nm to an integrated value Z¹ of an emission intensity in a wavelength range from 600 nm to 800 nm is 0.600 or more.

8. The light-emitting device according to any one of claims 1 to 7, wherein
the light-emitting device has a light emission peak wavelength in a wavelength range from 590 nm to 620 nm in the emission spectrum, and emits light having a half-value width of 90 nm or less.

9. The light-emitting device according to any one of claims 1 to 8, wherein
in the wavelength conversion member, a ratio of a content of the second phosphor to a total content of the first phosphor and the second phosphor is in a range from 35 mass % to 80 mass %.
